(19) United States
(12) Patent Application Publication
(10) Pub. No.: US 2026/0348763 A1
(43) Pub. Date: Nov. 5, 2026

(54) CAVITY POWER METER AND METHOD FOR MEASURING THE POWER OF ELECTROMAGNETIC RADIATION

(71) Applicant: INSTITUT NATIONAL D'OPTIQUE, Quebec (CA)

(72) Inventors: Bruno TREMBLAY, Quebec (CA); Francis PICARD, Quebec (CA)

(21) Appl. No.: 19/111,832

(22) PCT Filed: Oct. 24, 2022
(86) PCT No.: PCT/CA2022/051563

§ 371 Date: Mar. 14, 2025

(51) Int. Cl. G01J 5/20

(52) U.S. Cl. CPC G01J 5/20; G01J 2005/202

(57) ABSTRACT

A cavity power meter and a method for measuring the power of electromagnetic radiation incident on the cavity power meter. The cavity power meter includes a plurality of sensing walls, each sensing wall including an inner surface and a plurality of microbolometers connected to the inner surface, the microbolometers being part of a measurement circuit. The cavity power meter also includes an aperture wall connected to the sensing walls, the sensing walls and the aperture wall being arranged to enclose a volume defining a measurement cavity, the plurality of microbolometers of each sensing wall being disposed in the measurement cavity. The aperture wall has an aperture defined therethrough to allow the electromagnetic radiation incident thereon to enter into the measurement cavity and to illuminate at least a portion of the microbolometers, thereby providing measurement of the power of the incident electromagnetic radiation.

### TECHNICAL FIELD

The present application relates to cavity power meters and to methods for measuring the power of electromagnetic radiation by using such cavity power meters.

### BACKGROUND

In the fields of optics and photonics, power meters are essential tools permitting the measurement of electromagnetic (EM) power. The response bandwidth or spectral band (frequency/wavelength response range) generally varies between different types of power meters, also referred to as detectors. If measuring a broad range of EM sources or signals, it is common to make use of different power meters adapted to each range. In addition, some spectral ranges are either sparsely or poorly covered, which is often the case in the terahertz (THz) frequency range.

One proposed solution for covering a broad range of EM wavelengths is a type of power meter referred to as a trap detector. Trap detectors are generally formed from a combination of multiple discrete detectors, where reflections of the EM radiation off one detector are received by another detector in order to increase the fraction of the incoming radiation absorbed overall, thereby improving the efficiency over one detector. Due to the limited number of reflections possible (limited by the number of discrete detectors), this approach may not lend itself to a complete absorption of the incident radiation and to a high responsivity. The extent of the useful spectral range for which the trap detector response is uniform may also be less than ideal.

Other proposed solutions include detectors with cavities, such as integrating spheres, to measure the power of EM radiation over various spectral ranges. Some cavity-based detectors are equipped with an absorbing layer covering the cavity inner walls and are arranged to trap EM radiation within the cavity until all the radiation is absorbed, generally over many reflections. A heating layer, made of an electrically resistive material, is generally located underneath the absorbing layer. The cavity detector further requires a temperature sensor, often a thermopile, located at an adequate position inside the cavity to measure a temperature representative of the cavity inner wall temperature. While the cavity-based arrangement generally responds over a wider wavelength range, cost and operational complexity may be increased relative to the discrete trap detector model.

There therefore remains a desire for solutions for detector systems for wide-band EM measurement.

### SUMMARY

It is an object of the present technology to improve the cavity power meters of the prior art. Developers of the present technology have developed various embodiments thereof based on their appreciation of at least one technical problem associated with the prior art approaches for measuring the power of electromagnetic (EM) radiation.

In accordance with broad aspects of the present technology, there is provided a cavity power meter forming a closed measurement cavity generally lined with electrically interconnected microbolometers. The microbolometers, having a wide absorption spectrum and including a resistor element (thermistor) whose resistance varies with the temperature, act as thermal detectors. By enclosing walls lined with microbolometers to form a cavity, electromagnetic radiation reflected or scattered by any given microbolometer is redirected to another one of the microbolometers and is then subject to many reflections, further increasing the absorption efficiency. The configuration of a cavity detector implementing walls covered with electrically interconnected microbolometers thus provides a thermal detector in which temperature sensors and heating apparatus (for example for electrical substitution measurement methods) may be omitted. Based on standard types of microbolometers, the cavity and microbolometer arrangement of the present technology provides for a generally uniform response over the wavelength range from 380 nm to 3 mm, corresponding to the frequency range from 0.1 to 790 THz.

In accordance with one broad aspect of the present technology, there is provided a cavity power meter including a plurality of sensing walls, each sensing wall of the plurality of sensing walls including an inner surface, and a plurality of microbolometers connected to the inner surface, the plurality of microbolometers being part of a measurement circuit; an aperture wall connected to the plurality of sensing walls, the plurality of sensing walls and the aperture wall being arranged to enclose a volume defining a measurement cavity, the plurality of microbolometers of each sensing wall being disposed in the measurement cavity, the aperture wall having an aperture defined therethrough, the aperture allowing electromagnetic radiation incident thereon to enter into the measurement cavity and to illuminate at least a portion of the plurality of microbolometers, thereby providing measurement of a power of the incident electromagnetic radiation.

In some embodiments, for each sensing wall, the plurality of microbolometers is arranged in a two-dimensional electrically interconnected array over the inner surface.

In some embodiments, the aperture wall includes an interior layer of reflective material.

In some embodiments, the interior layer of reflective material is formed from at least one of gold; aluminum; and silver.

In some embodiments, the cavity power meter further includes a plurality of aperture-wall microbolometers disposed on an inner surface of the aperture wall, the plurality of aperture-wall microbolometers being operatively connected to the plurality of microbolometers.

In some embodiments, for each sensing wall, the plurality of microbolometers covers a major portion of the inner surface.

In some embodiments, the aperture is a through-hole; and the aperture allows ambient air to flow in and out of the measurement cavity.

In some embodiments, the cavity power meter further includes a window disposed in the aperture; and the window sealingly closes the measurement cavity.

In some embodiments, the plurality of sensing walls, the aperture wall, and the window are configured to maintain the measurement cavity in a vacuum condition.

In some embodiments, at least one microbolometer of the plurality of microbolometers comprises an optically absorptive layer disposed on a cavity-side surface of the at least one microbolometer.

In some embodiments, the optically absorptive layer includes at least one of gold black; carbon nanotubes; and graphene.

In some embodiments, at least one sensing wall of the plurality of sensing walls further comprises a reflective layer disposed on at least a portion of the inner surface of the at least one sensing wall.

In some embodiments, the cavity power meter further includes a plurality of reference microbolometers thermally connected to the inner surface of at least one sensing wall of the plurality of sensing walls; and the plurality of microbolometers is a plurality of measurement microbolometers; and the plurality of reference microbolometers is disposed in thermal contact with the at least one sensing wall.

In some embodiments, the plurality of sensing walls includes a plurality of rectangularly-shaped sensing walls; the aperture wall is rectangularly-shaped; and the cavity power meter is in a rectangular cuboid form.

In some embodiments, the aperture wall and the rectangularly-shaped sensing walls are square shaped; and the cavity power meter is in a cube form.

In some embodiments, the plurality of sensing walls includes a plurality of triangularly-shaped sensing walls; and the aperture wall and the plurality of triangularly-shaped sensing walls have a pyramidal shape.

In some embodiments, the plurality of triangularly-shaped sensing walls includes three triangularly-shaped sensing walls; the aperture wall is triangularly-shaped; and the cavity power meter is in a triangular pyramid form.

In some embodiments, the plurality of triangularly-shaped sensing walls includes four triangularly-shaped sensing walls; the aperture wall is square shaped; and the cavity power meter is in a square pyramid form.

In some embodiments, the plurality of triangularly-shaped sensing walls includes six triangularly-shaped sensing walls; the aperture wall is hexagonally shaped; and the cavity power meter is in a hexagonal pyramid form.

In some embodiments, the cavity power meter further includes a Wheatstone bridge circuit operatively connected to the plurality of reference microbolometers and the plurality of measurement microbolometers, the Wheatstone bridge circuit partially forming the measurement circuit.

In some embodiments, the cavity power meter further includes a capacitive trans-impedance amplifier (CTIA) circuit operatively connected to the plurality of reference microbolometers and the plurality of measurement microbolometers, the CTIA assembly partially forming the measurement circuit.

In accordance with another broad aspect of the present technology, there is provided a method for measuring power of electromagnetic (EM) radiation using a cavity power meter, the cavity power meter including a plurality of electrically-interconnected microbolometers. The method includes determining a change in at least one operational value across the plurality of electrically-interconnected microbolometers using an electrical substitution process, the change being due, at least in part, to the EM radiation entering a measurement cavity of the cavity power meter; and measuring the power of the EM radiation, based on the change in the at least one operational value across the plurality of electrically-interconnected microbolometers, using the electrical substitution process including determining an initial electrical resistance across the plurality of electrically-interconnected microbolometers, the initial electrical resistance being indicative of an initial temperature of the microbolometers, the initial electrical resistance being determined prior to the EM radiation entering the cavity power meter; causing the EM radiation to enter the measurement cavity; subsequent to the EM radiation entering the measurement cavity, determining an illumination electrical resistance across the plurality of electrically-interconnected microbolometers, the illumination electrical resistance being indicative of an effective illumination temperature of the microbolometers; subsequent to determining the illumination electrical resistance, causing the EM radiation to discontinue entering the measurement cavity; subsequent to causing the EM radiation to discontinue entering the measurement cavity, allowing the plurality of electrically-interconnected microbolometers to cool; subsequent to allowing the plurality of electrically-interconnected microbolometers to cool, applying a substitution voltage across the plurality of electrically-interconnected microbolometers causing the plurality of electrically-interconnected microbolometers to return to the illumination electrical resistance; and determining the power of the EM radiation based on the substitution voltage.

Quantities or values recited herein are meant to refer to the actual given value. The term “about” is used herein to refer to the approximation to such given value that would reasonably be inferred based on the ordinary skill in the art, including equivalents and approximations due to the experimental and/or measurement conditions for such given value.

In the context of the present specification, unless expressly provided otherwise, “controller,” “computer,” “computer implemented-device,” and “processing unit” include any hardware and/or software appropriate to the relevant task at hand. Thus, some non-limiting examples of hardware and/or software include computers (servers, desktops, laptops, netbooks, etc.), smartphones, tablets, network equipment (routers, switches, gateways, etc.) and/or combination thereof.

Embodiments of the present technology each have at least one of the above-mentioned objects and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 is a front, side perspective view of a cavity power meter according to a non-limiting embodiment of the present technology;

FIG. 2 is a front elevation view of the cavity power meter of FIG. 1;

FIG. 3 is a cross-sectional view of the cavity power meter of FIG. 1, taken along line 3-3 of FIG. 2;

FIG. 4 is a schematic, elevation view of one sensing wall of the cavity power meter of FIG. 1, shown in isolation;

FIG. 5 is a schematic illustration of the electrical interconnections of a microbolometer array of the sensing wall of FIG. 4;

FIG. 6 is a detailed view of the microbolometer array of FIG. 4;

FIG. 7 is a perspective view of a microbolometer of the microbolometer array of FIG. 4, shown in isolation;

FIG. 8 is a front, side perspective view of a cavity power meter according to another non-limiting embodiment of the present technology;

FIG. 9 is a front, side perspective view of a cavity power meter according to yet another non-limiting embodiment of the present technology;

FIG. 10 is a front, side perspective view of a cavity power meter according to yet another non-limiting embodiment of the present technology;

FIG. 11 is a front elevation view of a cavity power meter according to yet another non-limiting embodiment of the present technology;

FIG. 12 is a cross-sectional side view of the cavity power meter of FIG. 11, taken along line 12 -12 of FIG. 11;

FIG. 13 is a cross-sectional view of a cavity power meter according to yet another non-limiting embodiment of the present technology;

FIG. 14 is a partial cross-sectional view of a cavity power meter according to yet another non-limiting embodiment of the present technology; and

FIG. 15 is a schematic diagram of a non-limiting embodiment of a method of measuring the power of electromagnetic radiation using the cavity power meter of FIG. 1.

The drawings are not necessarily drawn to scale and may be illustrated by phantom lines, diagrammatic representations and fragmentary views. In certain instances, details that are not necessary for an understanding of the embodiments or that render other details difficult to perceive may have been omitted. It should further be noted that throughout the appended drawings, like features are identified by like reference numerals.

### DETAILED DESCRIPTION

Reference will now be made in detail to various non-limiting embodiments for an optical system and components disposed therein. It should be understood that other non-limiting embodiments, modifications and equivalents will be evident to one of ordinary skill in the art in view of the non-limiting embodiments disclosed herein and that these variants should be considered to be within the scope of the appended claims. Furthermore, it will be recognized by one of ordinary skill in the art that certain structural and operational details of the non-limiting embodiments discussed hereafter may be modified or omitted altogether (i.e. non-essential). In other instances, well known methods, procedures, and components have not been described in detail.

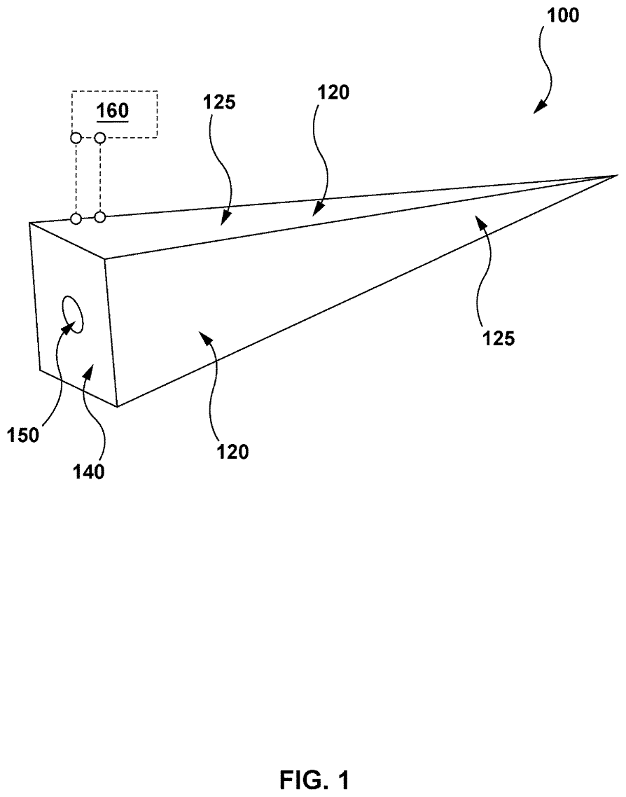

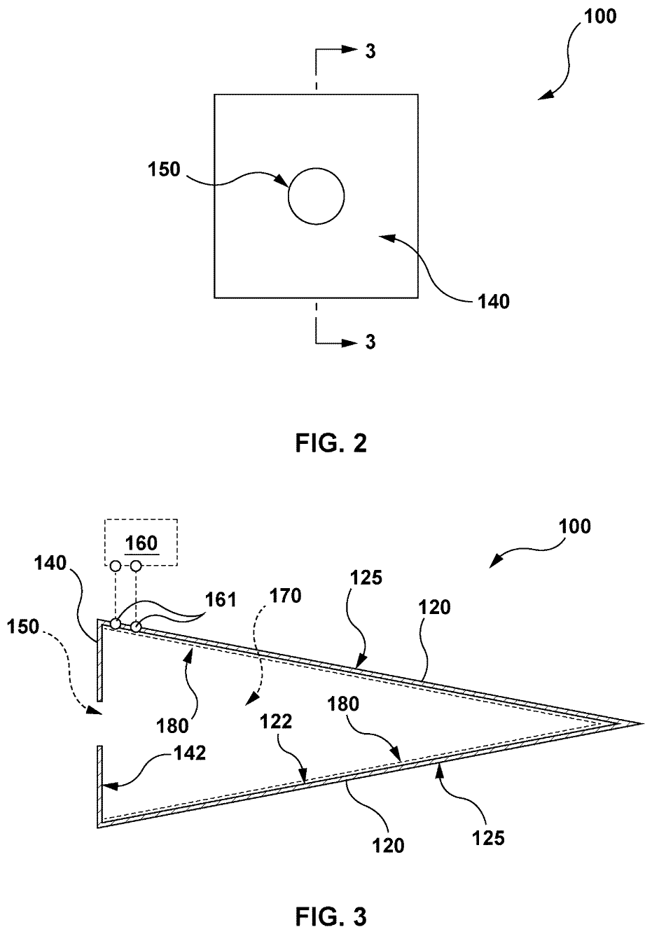

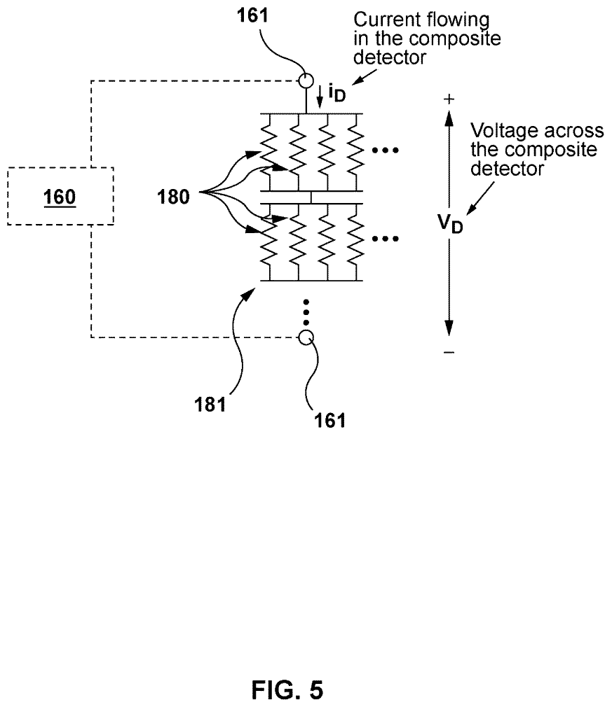

A cavity power meter 100, also referred to herein as the meter 100, according to one non-limiting embodiment of the present technology is illustrated in FIGS. 1 to 3. As will be set out below in more detail, the meter 100 forms a cavity 170 lined with a plurality of microbolometers 180 for measuring the power of electromagnetic (EM) radiation. An example microbolometer arrangement is illustrated in FIG. 5, described in more detail below. Broadly, the microbolometers 180 provide broadband absorption of EM radiation directed into the cavity 170. EM radiation entering the cavity 170 illuminates at least a portion of the microbolometers 180, which provide a measurement of the power of the incident EM radiation. By lining the interior of the meter 100 with the microbolometers 180, the meter 100 also benefits from the efficiency of a cavity-type detector, where the incoming EM radiation may undergo multiple reflections but remains generally trapped therein. Portions of the EM radiation reflected or scattered from one microbolometer 180 will then generally be incident on other microbolometers 180. Many reflections within the cavity 170 are possible, thereby increasing the fraction of the power of the incident EM radiation that is absorbed and then detected.

It is noted that the meter 100 and various embodiments thereof are generally represented herein by the electromagnetic energy absorbing portion (also referred to as a measurement head, formed by the walls 120, 140) along with the measurement circuit 160. As would be recognized by a person of skill in the art, additional components and/or structures could be included in the meter 100 as illustrated without departing from the present technology.

The meter 100 includes a plurality of sensing walls 120, specifically four triangularly-shaped sensing walls 120 in the present embodiment. The meter 100 also includes a square-shaped aperture wall 140, connected to the sensing walls 120. The walls 120, 140 are connected together and arranged to enclose a volume defining the measurement cavity 170. In the illustrated embodiment, the cavity power meter 100 is in a square pyramid form, with an apex of the square pyramid being disposed opposite the aperture wall 140. As will be described in more detail below, other embodiments of the meter 100 having different forms are also contemplated.

Each sensing wall 120 includes an inner surface 122, the word “inner” referring herein to the surface nearest the interior measurement cavity 170. The microbolometers 180 of each sensing wall 120 are thus disposed in the measurement cavity 170. Each sensing wall 120 also includes an outer surface 125, opposite the inner surface 122. The outer surfaces 125 of the walls 120 form an exterior surface of the meter 100 and generally are configured and arranged to block incident EM radiation from entering into the measurement cavity 170 through the walls 120. In the present embodiment, each sensing wall 120 is formed from silicon (Si) substrates, on which are disposed microbolometers (described below). In some embodiments, the walls 120 could be formed from other substrate materials, generally selected according to the required very low roughness and high degree of flatness.

Without limiting the present technology, various methods for supporting and connecting the walls 120 are contemplated. For example, the walls 120 could be mounted to a flexible support (such as a flexible printed circuit board) which is then flexed to form the cavity 170. In some embodiments, the walls 120 could be mounted to a frame, formed for instance from metal or plastic rods. In at least some embodiments, a metal coating or layer could be deposited on the inner surface 122 and/or outer surface 125 of the wall 120 to impede infiltration (via transmission) of EM radiation through the wall 120. In embodiments utilizing a frame to support the walls 120, it is also contemplated that additional EM radiation blocking panels or materials could be connected to the frame, exterior to the walls 120. It is contemplated that additional treatment or materials could be applied to the outer surfaces 125 in order to further block out incident EM radiation from the measurement cavity 170.

The aperture wall 140 is connected to the sensing walls 120, specifically the exterior edges of the aperture wall 140 are each affixed to one edge of each of the sensing walls 120. The aperture wall 140 has an aperture 150 defined therethrough. The aperture 150 allows the EM radiation directed to the aperture 150 to enter into the measurement cavity 170 and then its power to be measured. In the embodiment of FIG. 1, the aperture 150 is a through-hole which allows ambient air to flow in and out of the measurement cavity 170.

As is illustrated in FIG. 3, the aperture wall 140 includes an interior layer 142 of reflective material attached or applied thereto. A variety of broadband reflective materials could be used, depending on the embodiment. The interior layer 142 of reflective material could be formed from, but it is not limited to: gold, aluminum, and silver. In some cases, additional adhesion layers could also be included in the interior layer 142. For example, a gold reflective layer could be deposited on an adhesion layer formed from chromium or titanium. The purpose of the reflective layer 142 is to return the intracavity EM radiation directed thereon back toward the microbolometers 180, with a minimum of absorption losses.

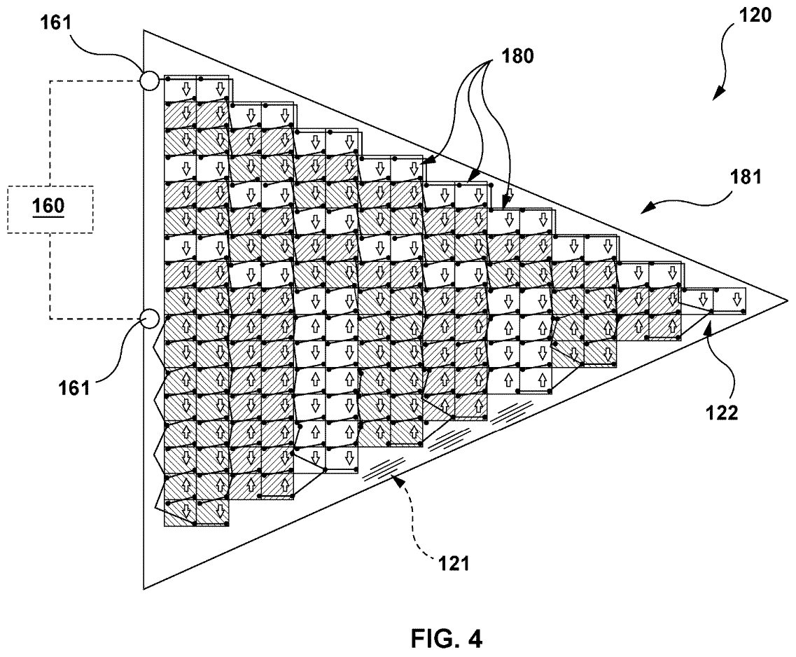

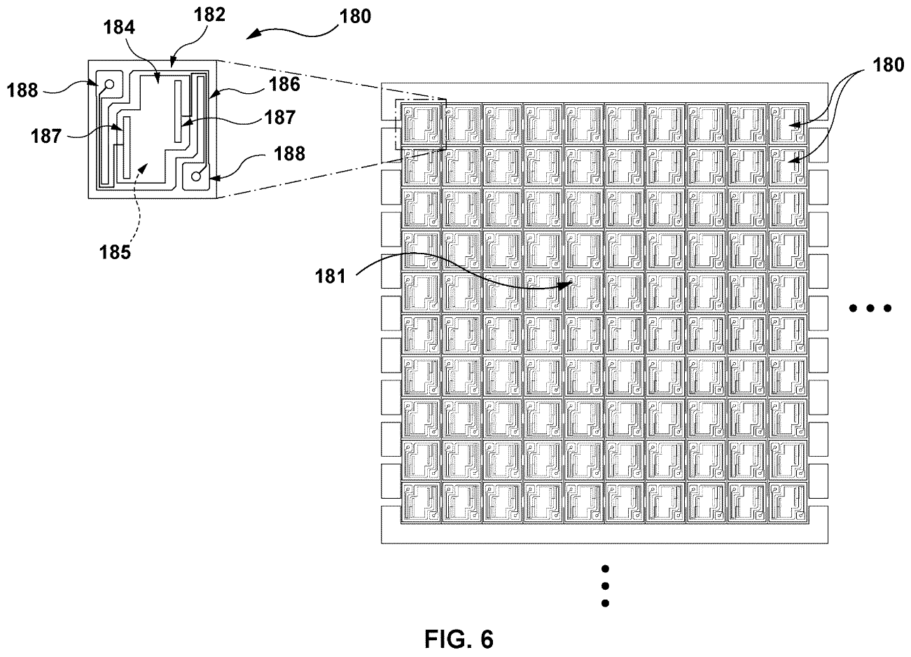

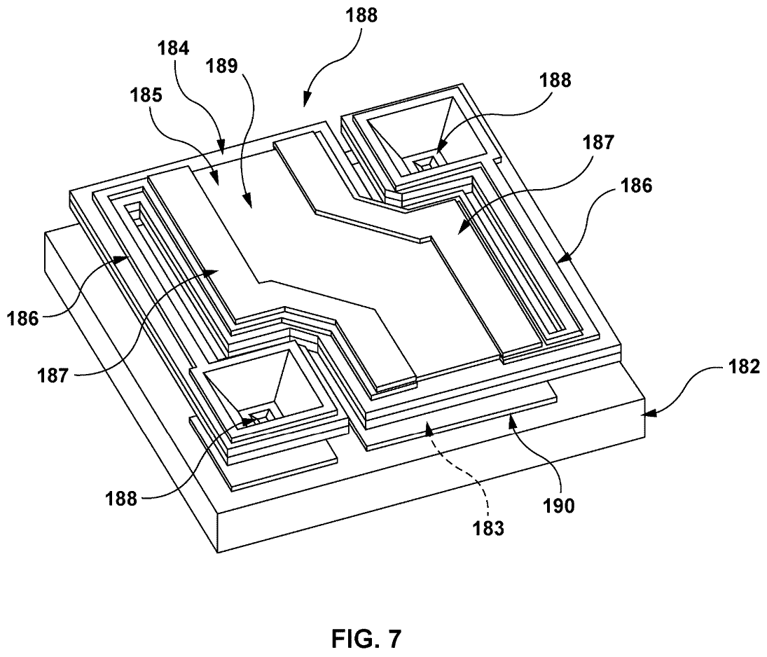

With additional reference to FIGS. 4 to 6, the microbolometers 180 will be described in more detail. The microbolometers 180 are part of a measurement circuit 160 (shown schematically) for measuring a resistance of the microbolometers 180 and communicatively connecting the microbolometers 180 with an interface (not shown) to provide an EM power measurement to a user. For example, the interface could be implemented by a computer-implemented device, including but not limited to: a personal computer, a computer network, a smart device, etc. Specific components and arrangements of the measurement circuit 160 are not specifically limited by the present technology and need not be detailed herein. The determination of the EM power received in the measurement cavity 170 based on the measured resistance is described in more detail below.

Each microbolometer 180 is mechanically connected to the inner surface 122 of its corresponding sensing wall 120 such that the sensing walls 120 support and position the microbolometers 180 in the cavity 170. As is illustrated in FIGS. 4 to 6, the microbolometers 180 of each sensing wall 120 are arranged in a two-dimensional electrically interconnected array 181 over the inner surface 122. Each sensing wall 120 includes two electrical terminals 161, also referred to as contacts 161, for connecting to the measurement circuit 160 and to the remaining sensing walls 120. In at least some embodiments, additional terminals could be included to provide for different connection arrangements between the walls 120. The microbolometers 180 preferably cover a major portion of the inner surface 122 of each sensing wall 120. As can be seen in FIG. 4, the array 181 is preferably arranged to maximize coverage of the inner surface 122, including varying the shape of the array 181 in order to maximize a fill factor when mounted on a triangular wall 120. Depending on the shape of the sensing wall 120, different arrangements of the array 181 and different fill factors of the inner surface 122 could be implemented.

The microbolometers 180 are electrically interconnected in a parallel-series scheme between the two terminals 161. This interconnection scheme is illustrated schematically in FIG. 5, with the microbolometers 180 being represented by resistor symbols. The interconnected microbolometers 180 in the array 181 are generally chosen to have identical operation characteristics. As such, the operation of each microbolometer 180, in terms of voltage across and the current flowing therethrough is generally the same when exposed to a same level of incident EM radiation. The microbolometers 180 thus generally exhibit similar responsivities and similar noise equivalent powers (NEPs). The array 181 of interconnected microbolometers 180 of each sensing wall 120 can then be treated as a single equivalent bolometer/detector in the measurement circuit 160. It is noted that while a rectangular array of microbolometers 180 is the most readily visualized arrangement for a parallel-series interconnection scheme, the present technology encompasses parallel-series interconnection arrangements suited for non-rectangular walls as well. FIG. 4 illustrates one non-limiting example of an interconnection scheme. Other interconnection arrangements are contemplated, including for example computer-generated custom routing designs. It is further noted that additional intermediate grouping of the microbolometers 180 could be required for at least some arrangements that include, for instance, devices with a large number of microbolometers 180. In some cases, a CAD-based tool could be used for determining a workable layout for the microbolometers 180.

The equivalent detectors of the sensing walls 120 are then connected in series, although the specific circuitry paradigm could vary in different embodiments. Within the limitation of maintaining a same current and voltage across each of the interconnected microbolometers 180, different connection configurations are contemplated. In at least some embodiments, the connection between walls 120 could be formed in parallel or parallel-series arrangements.

With additional reference to FIG. 7, one of the microbolometers 180 is illustrated in detail. As the microbolometers 180 used in a same cavity power meter 100 are generally identical, only one microbolometer 180 will be described. It is contemplated that different embodiments of microbolometers could be used within the meter 100 in some cases.

The microbolometer 180 includes a substrate 182 supporting the remaining components of the microbolometer 180. The substrate 182 is formed from silicon (Si), but it is contemplated that different materials could be used. The microbolometer 180 includes a platform 184 distanced from the substrate 182. The platform 184 is supported by two legs 186. At their distal ends, each leg 186 is integrally formed with a post 188 disposed on the substrate 182. The legs 186 extend essentially horizontally and the height of the posts 188 is selected to provide a vertical clearance 183, also referred to as a gap 183, between the platform 184 and the substrate 182. The gap 183, in combination with the small cross-section of the legs 186, provides a substantial thermal insulation of the platform 184, relative to the substrate 182. The platform 184, the legs 186, and the posts 188 are formed from a plurality of structural layers (not separately identified) of dielectric materials, including generally silicon nitride. It is contemplated that different materials could be used for forming the platform 184, the legs 186, and the posts 188.

The microbolometer 180 also includes a thermistor 185 embedded in the platform 184. The thermistor 185 is made of a thin layer of an electrically-conducting material that exhibits an electrical resistivity that varies with the temperature. In the present embodiment, the thermistor material is vanadium oxide, which presents a high temperature coefficient of resistance (TCR), but other materials are contemplated, including but not limited to amorphous silicon. Specifically, the electrical resistance of the thermistor 185 changes as a function of the temperature of the platform 184. The microbolometer 180 also includes two electrodes 187 embedded in the platform 184. The electrodes 187 are disposed on opposite sides of the thermistor 185, on opposite edges of the platform 184. The electrodes 187 are formed from an electrically conductive material, generally a metal, including but not limited to: titanium, titanium nitride, and vanadium. The electrodes 187 are configured and arranged to be in electrical contact with the thermistor 185, allowing for detection and determination of a change in the electrical resistance of the thermistor 185 during operation of the meter 100.

In the present embodiment, the microbolometer 180 further includes an optically absorptive layer 189, also known simply as an optical absorber, disposed on a surface of the microbolometer 180 facing the cavity 170. Specifically, the optically absorptive layer 189 is deposited on the platform 184, over the thermistor 185. The optically absorptive layer 189 aids in improving the absorption and decreasing the overall reflectance of the microbolometer 180, aiding in improving the sensitivity of the meter 100. Depending on the embodiment, different optically absorptive materials could be used, including, but not limited to, gold black, carbon nanotubes, and graphene. It is contemplated that in some instances the optically absorptive layer 189 could be absent from the microbolometers 180, although it is noted that the spectral response curve of the meter 100 could be affected to some extent.

The microbolometer 180 further includes, in the present embodiment, a reflective layer 190, also referred to as a platform mirror 190. The platform mirror 190 is disposed under the platform 184 and is generally fabricated from a layer of metallic material. The platform mirror 190 is configured to reflect the part of the incident EM radiation that is transmitted through the platform 184 back toward the platform 184. With a second pass through the platform 184, the absorption of EM radiation of each microbolometer 180 is generally increased with inclusion of the platform mirror 190.

It is noted that the structure of the microbolometer 180 described herein is simply one non-limiting example of such a structure. Different types of microbolometers, including different configurations of the support structure separating the platform from the substrate, for example, could be implemented.

Each microbolometer 180, specifically of the embodiment described herein, functions broadly as follows. The microbolometer 180 detects the EM radiation incident thereon through a temperature increase produced by the part of the radiation that is absorbed by the various layers that form the platform 184. The change in temperature causes a change in the electrical resistance of the thermistor 185. The change in resistance of the thermistor 185 is thus indicative of the quantity of EM radiation absorbed by the corresponding microbolometer 180. The gap 183 provides thermal insulation of the platform 184 to aid in increasing the change in the temperature of the thermistor 185 for a given absorbed optical power, thereby aiding in increasing responsivity. A variety of procedures known in the art can then be used to generate an electrical signal indicative of this change in the electrical resistance of the thermistor 185; specifics will thus not be discussed further herein.

As is briefly noted above, the microbolometers 180 are fabricated on flat substrates 182, sized and shaped to be spatially arranged into two-dimensional arrays 181 and to form the cavity 170. It is noted that the microbolometers 180 are generally fabricated on circular substrates per common microfabrication techniques; the substrates are subsequently cut to conform to the shape of the wall 120. The flat substrate structure limits the shape of the interior walls of the meter 100, as the microbolometers 180 cannot generally be fabricated on curved substrates. By the present technology, the meter 100 thus will generally be limited to have a plurality of flat walls and will not take the shape of a sphere or cone.

In the present embodiment, each sensing wall 120 further includes a reflective layer 121 disposed on portions of the inner surface 122. The reflective layer 121, formed from a same or different material as the reflective layer 142 of the aperture wall 140, is disposed on portions of the inner surface 122 not otherwise covered by the microbolometers 180. An example of a portion of the inner surface 122 covered with a reflective layer 121 is depicted in FIG. 4. The reflective layer 121 aids in improving the efficiency of the meter 100 by reflecting EM radiation impinging the inner surface 122 back into the cavity 170 for subsequent absorption by the microbolometers 180. It is contemplated that the reflective layer 121 could be omitted from one or more of the sensing walls 120.

Depending on the specific embodiment or application, the meter 100 could include additional components that need not be described herein, including but not limited to: support structures, mechanical stages, power supplies, microbolometer readout circuits, control hardware and/or software, electronic systems, etc.

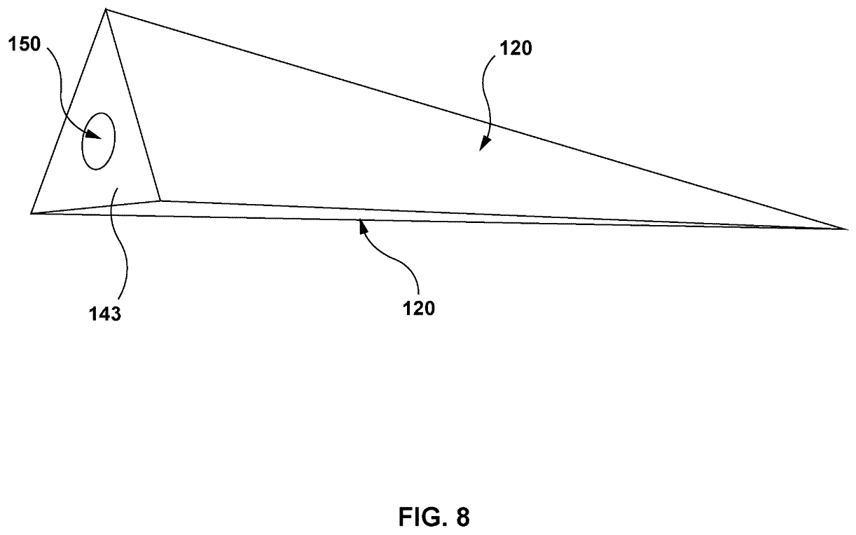

While the above described embodiment of the meter 100 is in the form of a square pyramid, different shapes of power meters are contemplated. Another non-limiting embodiment of a cavity power meter 103 according to the present technology is illustrated in FIG. 8. Elements of the cavity power meter 103 that are similar to those of the cavity power meter 100 retain the same reference numerals and will generally not be described again.

The cavity power meter 103 is in the form of a triangular pyramid. The cavity power meter 103 thus has a triangularly-shaped aperture wall 143 defining the aperture 150 and three triangularly-shaped sensing walls 120 interconnected and connected to the aperture wall 143. As is the case for the meter 100, the particular triangular shape and aspect ratio of the sensing walls 120 of the meter 103 could vary from those of the embodiment illustrated in FIG. 8.

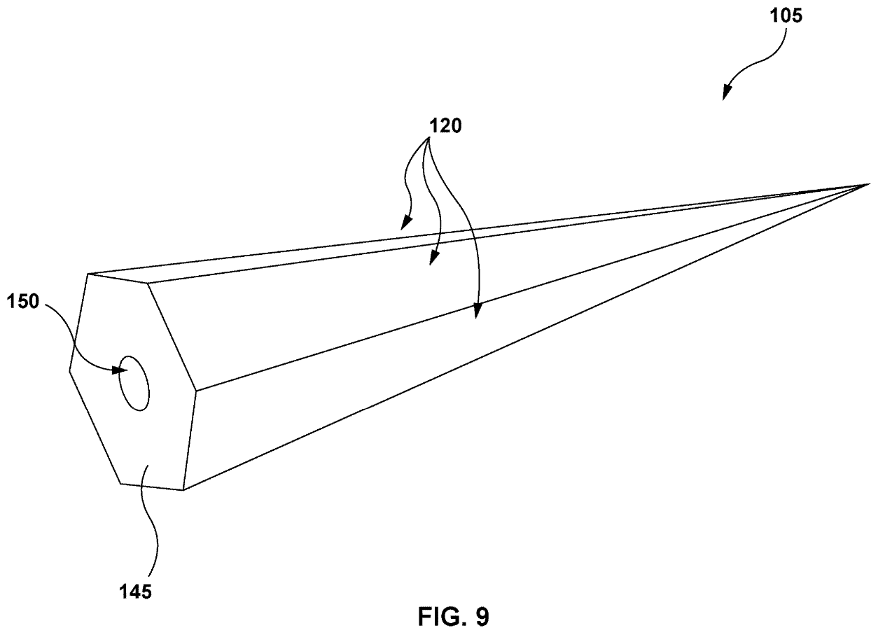

Yet another non-limiting embodiment of a cavity power meter 105 according to the present technology is illustrated in FIG. 9. Elements of the cavity power meter 105 that are similar to those of the cavity power meter 100 retain the same reference numerals and will generally not be described again.

The cavity power meter 105 is in the form of a hexagonal pyramid. The cavity power meter 105 has a hexagonally-shaped aperture wall 145 defining the aperture 150 and six triangularly-shaped sensing walls 120 interconnected and connected to the aperture wall 145. As is the case for the meter 100, the particular triangular shape and aspect ratio of the sensing walls 120 of the meter 105 could vary from those in the illustrated embodiment.

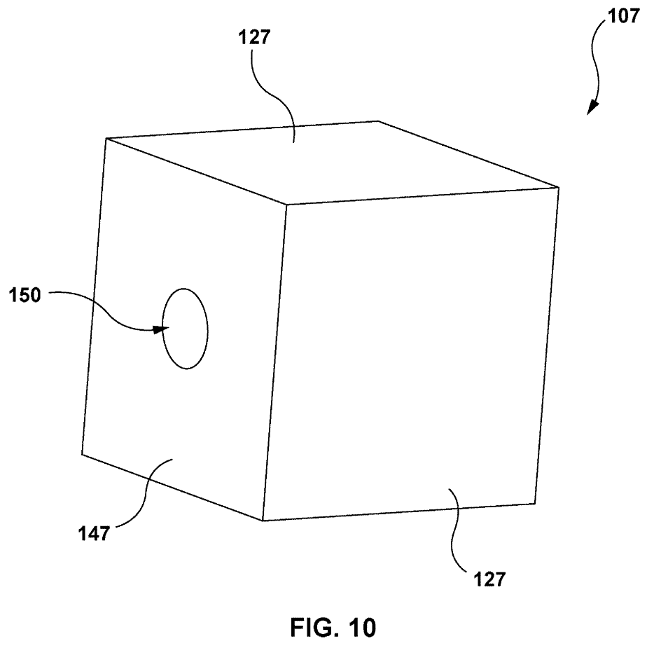

Yet another non-limiting embodiment of a cavity power meter 107 according to the present technology is illustrated in FIG. 10. Elements of the cavity power meter 107 that are similar to those of the cavity power meter 100 retain the same reference numerals and will generally not be described again.

The cavity power meter 107 is in the form of a cube. The cavity power meter 107 has a square aperture wall 147 defining the aperture 150 and five square-shaped sensing walls 127 interconnected and connected to the aperture wall 147. It is similarly contemplated that four rectangular sensing walls could be connected to the aperture wall 147 and the square shaped sensing wall 127 disposed opposite the aperture wall 147, forming a meter in a rectangular cuboid form. As will be apparent to the person of skill in the art, such power meters where there is a sensing wall opposite and parallel to the aperture wall and/or when the meter is generally cubic in form are prone to back reflections of the EM radiation that penetrates into the cavity. At least some embodiments of cube power meters, however, are still workable solutions, as remission from the microbolometers 180 is generally formed from not only specular reflection, but also diffuse reflection, diffraction, and thermal emission.

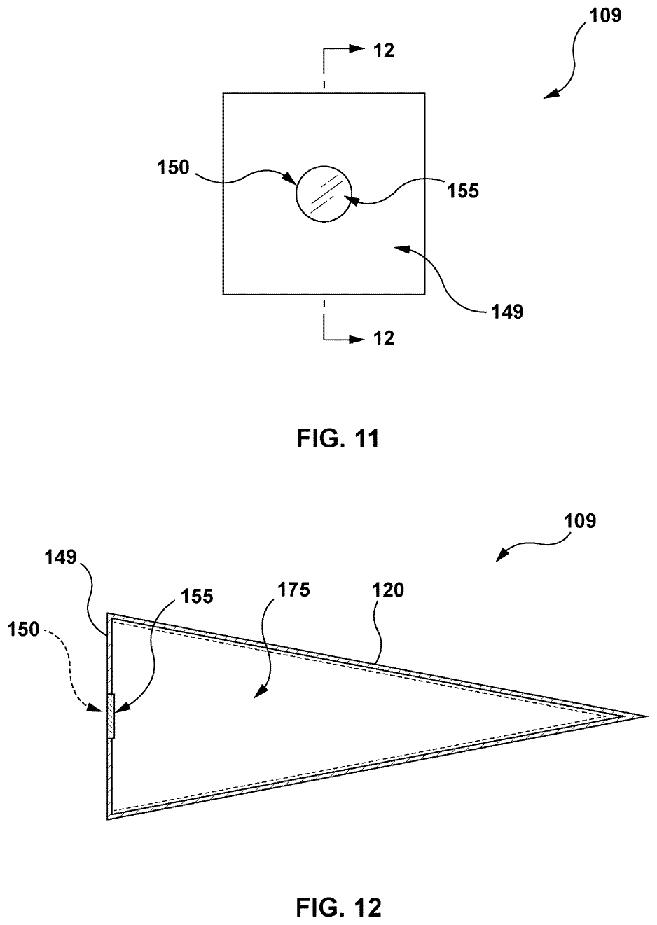

Another implementation of a meter 109 according to the present technology is illustrated in FIGS. 11 and 12. Elements of the meter 109 that are similar to those of the meter 100 retain the same reference numerals and will generally not be described again.

In contrast to the aperture wall 140 of the meter 100, through which ambient air can flow in and out of the measurement cavity 170, the meter 109 is arranged to maintain vacuum in a vacuum measurement cavity 175. An aperture wall 149 of the meter 109 includes a window 155 disposed in the aperture 150. Specifically, the window 155 sealingly closes the vacuum measurement cavity 175, with the sensing walls 120, the aperture wall 149, and the window 155 being configured to maintain the measurement cavity 175 in a vacuum condition. Various optical materials and arrangements for the transmission window 155 could be used, depending on the embodiment. The materials could include but are not limited to: calcium fluoride (with a spectral transmission band of approximately 0.25 to 8.5 μm), sapphire (with a transmission band of approximately 0.3 to 5.5 μm), zinc selenide (with a transmission band of approximately 5.5 to 15.5 μm), fused silica (with a transmission band of approximately 0.3 to 2 μm), germanium (5 to 14 μm), and silicon (1 to 8 μm+25 to 1000 μm).

The EM radiation absorbed by microbolometers 180 maintained in vacuum in the measurement cavity 175 will generally produce a larger temperature increase of the microbolometers compared to embodiments with the measurement cavity 175 held at atmospheric pressure. The greater temperature increase in turn produces larger output response and signal-to-noise ratio for embodiments with vacuum-maintained measurement cavities 175. The spectral transmission bandwidth of the window 155, however, can limit the spectral response bandwidth of the meter 109, as any material chosen to form the window 155 may block at least some wavelength bands of the incident EM radiation. The window 155 can then act as a spectral filter for implementing bandwidth-limited power measurements. In contrast, the through-hole aperture 150 of the meter 100 presents fewer limitations to the wavelength of EM radiation entering the measurement cavity 170, with the acceptance wavelength band not being limited by a window material. It is noted, however, that air (gases) within the cavity may affect the power of the EM radiation being measured since absorption bands of the gases could affect measurement at the corresponding wavelengths.

In some cases, the meter 109 can benefit from the presence of a window 155 disposed in the aperture 150 even when the measurement cavity 175 is maintained at atmospheric pressure. For instance, the window 155 could be used for protecting the microbolometers 180 from being damaged during measurement runs performed in harsh environments, in the presence of corrosive vapors, humidity, or dust.

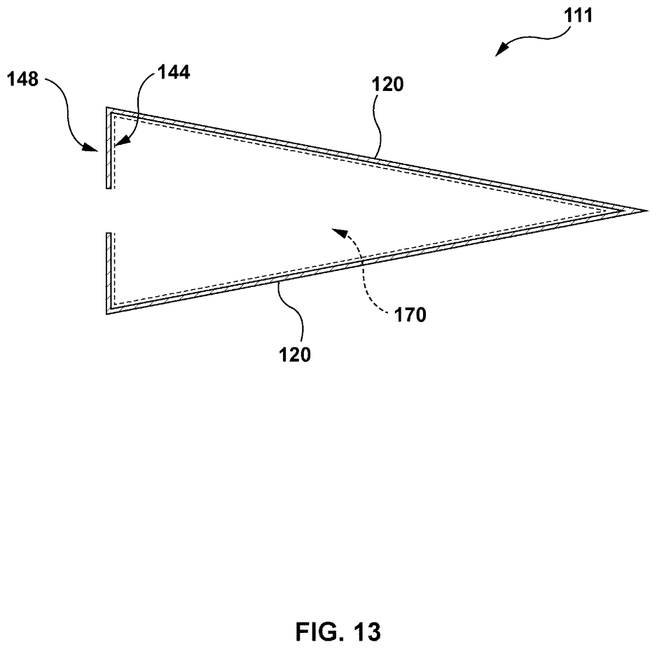

Yet another implementation of a meter 111 according to the present technology is illustrated in FIG. 13. Elements of the meter 111 that are similar to those of the meter 100 retain the same reference numerals and will generally not be described again.

The meter 111 includes an aperture wall 148 connected to the sensing walls 120. The aperture wall 148 includes an additional plurality of microbolometers 144 disposed on an inner surface of the aperture wall 148. The microbolometers 144 are electrically interconnected to the microbolometers 180 of the sensing walls 120, and form part of the measurement capability of the meter 111. It is contemplated that some portions of the aperture wall could include a reflective material and some other portions of the aperture wall could include microbolometers disposed thereon.

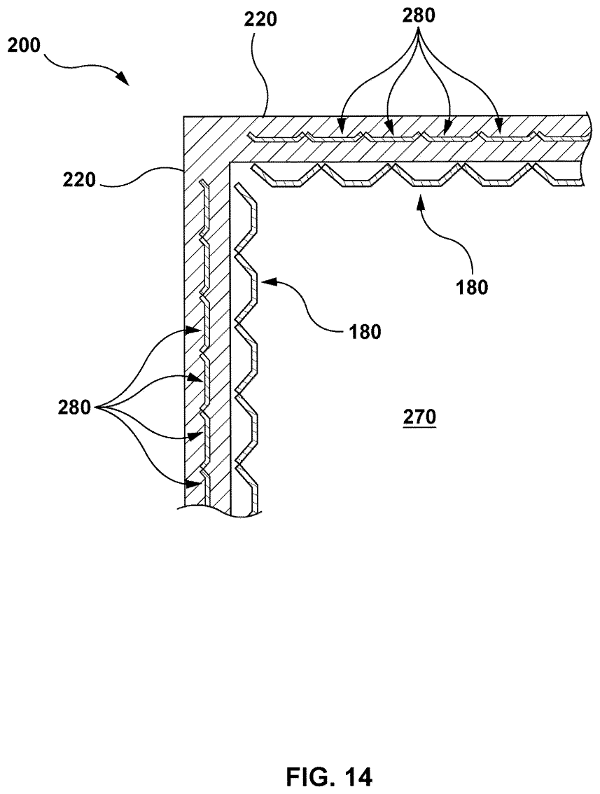

A limited portion of yet another implementation of a meter 200 according to the present technology is illustrated in FIG. 14. Elements of the meter 200 that are similar to those of the meter 100 retain the same reference numerals and will generally not be described again.

The meter 200 includes a plurality of sensing walls 220 connected to the aperture wall 140 (not shown in FIG. 14) and enclosing a measurement cavity 270. While not explicitly illustrated, the meter 200 could take the shape of any of the meters 100, 103, 105, 107, depending on details of the embodiment.

Each sensing wall 220 includes the microbolometers 180 for absorbing the EM radiation and measuring its power, as described above. Each sensing wall 220 of the meter 200 further includes a plurality of reference microbolometers 280 thermally connected to an inner surface of the sensing wall 220. The incorporation of reference microbolometers 280 in the sensing walls 220 is generally carried out by designing these walls as multi-layer structures wherein the reference microbolometers 280 and the microbolometers 180 are fabricated on separate substrates. These separate structures are then put into direct contact, possibly along with additional layers that provide better structural rigidity to the sensing walls 220. The reference microbolometers 280 are formed from the same materials as the microbolometers 180. However, their structural configuration generally differs somewhat from that of the microbolometers 180 since the platform 184 and the thermistor 185 are preferably disposed in direct contact with the substrate 182, i.e., there is no gap 183. As a result, the reference microbolometers 280 may be provided without legs 186 and posts 188.

The reference microbolometers 280, also referred to as thermally-shunted microbolometers or shunt microbolometers, are arranged and disposed in thermal contact with the sensing wall 220. As is illustrated in FIG. 14, the reference microbolometers 280 are in direct contact with the sensing wall 220 such that the reference microbolometers 280 are maintained at a same temperature as the walls 220. These microbolometers 280 are thus maintained at the ambient temperature, and they are never exposed to the EM radiation circulating in the measurement cavity 270. The reference microbolometers 280 therefore serve as a temperature reference to be used in some signal readout schemes to improve the accuracy of the power reading from the measurement microbolometers 180. Similarly to the microbolometers 180, the reference microbolometers 280 are electrically interconnected in a series-parallel connection structure such that the reference microbolometers 280 can be treated as one equivalent reference bolometer.

In some embodiments, it is contemplated that a capacitive trans-impedance amplifier (CTIA) circuit (not shown) could be operatively connected to the reference microbolometers 280 and to the measurement microbolometers 180, where the CTIA circuit could partially form the measurement circuit 160. It is also contemplated that the cavity power meter 100 could include a Wheatstone bridge circuit (not shown) operatively connected to the reference microbolometers 280 and to the measurement microbolometers 180, where the Wheatstone bridge circuit could partially form the measurement circuit 160. The CTIA circuit and/or the Wheatstone bridge circuit could be operated per normal measurement schemes in order to determine the power of the EM radiation incident on the meter 200.

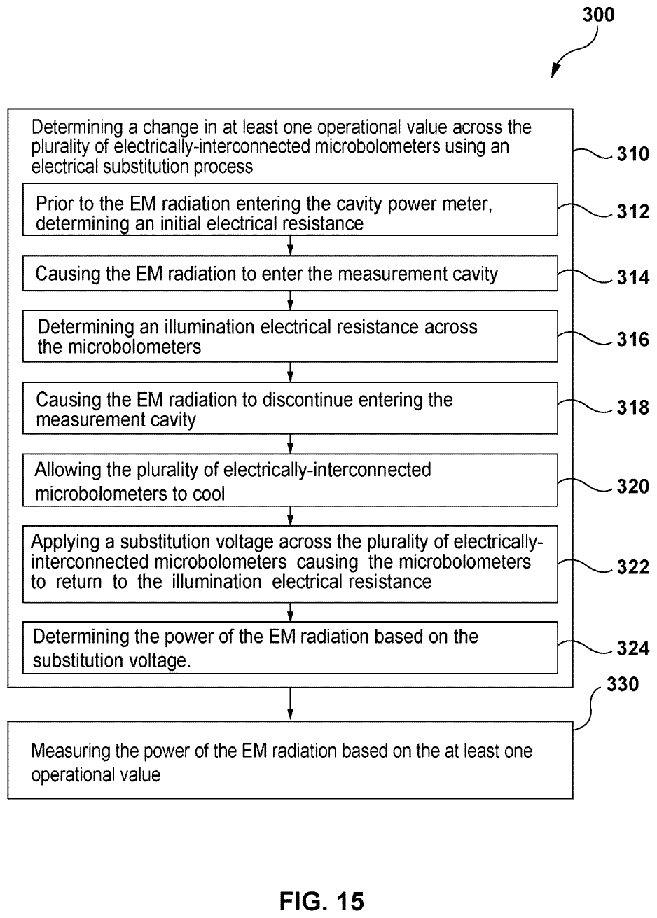

With reference to FIG. 15, a method 300 for measuring the power of EM radiation received by the cavity power meter 100 is illustrated. It is contemplated that the method 300 could also be implemented with at least some of the other embodiments of cavity power meters described above. Broadly, the meter 100 is configured and arranged to be used with an electrical substitution method, thereby providing a thermal-based power sensor while eliminating the requirement for a separate temperature sensor and a separate heating apparatus in the meter, the microbolometers 180 performing both the temperature sensing and heating functions when in operation.

The method 300 begins, at step 310, with determining a change in one or more operational values across the electrically-interconnected microbolometers 180. In the present embodiment, the operational value is a change in the resistance of the thermistor of one or more of the microbolometers 180. As is noted above, the electrical resistance of the thermistor of each microbolometer 180 depends on its temperature thereof. The change is thus due, at least in part, to the EM radiation entering the cavity power meter 100 and being absorbed by at least some of the microbolometers 180. An effective resistance change across the collection of microbolometers 180 thus indicates an effective temperature change within the meter 100. It is noted that the specific temperature change of any particular microbolometer 180 need not be separately identified, as it is expected that some of the microbolometers 180 will receive, and absorb, different quantities of the incoming EM radiation.

The method 300 then continues, at step 330, with determining or measuring the power of the EM radiation based on the change in the operational value across the electrically-interconnected microbolometers 180. In this embodiment, the EM radiation power measurement is thus based on a determination of a change in the resistance across the microbolometers 180 following introduction of the EM radiation into the cavity power meter 100.

By the present embodiment, the change in operational value is determined using an electrical substitution process. In different embodiments, it is contemplated that different processes or approaches could be used for operating the cavity power meter 100 or other above described versions.

The method 300 thus includes, at step 310, using an electrical substitution process. The electrical substitution process of step 310 begins, at substep 312, with determining an initial electrical resistance across the microbolometers 180 prior to the EM radiation entering the cavity power meter 100. As is mentioned above, the resistances of the thermistors 185 of the microbolometers 180 change with the temperature. The initial electrical resistance is thus indicative of an initial effective temperature of the microbolometers 180 of the cavity power meter 100.

The method 300 continues, at substep 314, with causing the incident EM radiation to enter the measurement cavity 170. In standard use, the EM radiation whose power is to be measured is directed into the aperture 150. In some embodiments, the meter 100 could include a shutter or beam blocker covering the aperture 150 and the method 300 could include removing such an obstacle to permit entry of the EM radiation into the measurement cavity 170.

The method 300 then continues, at substep 316, with determining an illumination electrical resistance across the microbolometers 180. As the microbolometers 180 absorb the EM radiation circulating into the measurement cavity 170, the temperature of the platform 184 of the one or more of the microbolometers 180 that absorb the EM radiation will increase, causing the resistances of the thermistors 185 of these microbolometers 180 to change as a function thereof. Once the temperature and resistance values have stabilized, the illumination resistance is determined. The illumination electrical resistance is indicative of an effective illumination temperature of the microbolometers 180. It is noted that the microbolometers 180 do not absorb equal amounts of the EM radiation, and thus do not have identical temperature changes when EM radiation is introduced into the measurement cavity 170 of the meter 100. The effective illumination temperature across the microbolometers 180, causing a change in the effective electrical resistance across the microbolometers 180, thus is representative of the power of the EM radiation absorbed by the microbolometers 180, without requiring a determination of temperature and resistance changes of any given one of the individual microbolometers 180. As is noted briefly above, the meter 100 thus does not require a temperature sensor in addition to the thermistor 185 embedded in the microbolometer platform 184.

The method 300 continues, at substep 318, with causing the EM radiation to discontinue entering the measurement cavity 170. Terminating the EM radiation exposure in the measurement cavity 170 could include turning off or redirecting the EM radiation source and/or blocking the aperture 150. Generally, in order to most accurately measure the difference in the electrical resistance between the illuminated and non-illuminated states, the measurement cavity 170 should be returned to its arrangement prior to receiving the EM radiation, i.e. to the arrangement that prevailed at substep 314.

The method 300 then continues, at substep 320, with allowing the microbolometers 180 to cool, i.e. to return to the initial effective temperature. This state is reached when the measured effective electrical resistance approaches the initial electrical resistance measured at substep 312. As the external wall surfaces of the meter 100 are thermally coupled to the surrounding air, the walls 120 generally act as a heat sink for the microbolometers 180. In the present embodiment, the time required for temperature stabilization of the microbolometers 180 is less than one second. The specific time constant between different thermal states (initial vs. illuminated, etc.) will depend on embodiment specifics such as the materials chosen for the various structural components of the meter 100.

Once the microbolometers 180 have returned to the initial effective temperature, the method 300 continues, at substep 322, with applying a substitution voltage across the microbolometers 180. The substitution voltage causes the temperature of the microbolometer platforms 184 to rise with respect to the initial effective temperature, thereby again changing the resistances of the thermistors 185. The substitution voltage is applied across the electrically-interconnected microbolometers 180 until causing them to return to the effective illumination temperature and the illumination electrical resistance previously determined.

The method 300 then concludes, at substep 324, with determining the power of the incident EM radiation based on the substitution voltage. The electrical power required to bring the microbolometers 180 of the meter 100 from an initial, not illuminated state to a state having the effective illumination temperature by the substitution voltage is equal to power of the EM radiation absorbed by the microbolometers 180 during illumination by the EM radiation. It is noted that any parameters affecting the thermal equilibrium in the non-illuminated state remain the same during the illumination phase (other than the EM radiation to be measured), the initial non-illumination phase, and the substitution voltage application phase (other than the change in applied voltage) in order to maintain accuracy in the electrical substitution method. For portions of the EM spectrum with full absorption by the cavity power meter 100, the electrical substitution method can thus give a generally absolute measurement of the EM radiation incident in the measurement cavity 170. In some cases, there may be portions of the EM spectrum where there is less than 100% of the incident EM radiation that is absorbed by the meter 100. In such cases, relative and absolute measurements may be performed; the latter requiring calibration for the considered portion of the EM spectrum.

It is noted that the foregoing has outlined some of the more pertinent non-limiting embodiments. It will be clear to those skilled in the art that modifications to the disclosed non-limiting embodiments can be affected without departing from the spirit and scope thereof. As such, the described non-limiting embodiments ought to be considered to be merely illustrative of some of the more prominent features and applications. Other beneficial results can be realized by applying the non-limiting implementations in a different manner or modifying them in ways known to those familiar with the art.

The mixing and/or matching of features, elements and/or functions between various non-limiting embodiments are expressly contemplated herein as one of ordinary skill in the art would appreciate from this disclosure that features, elements and/or functions of one embodiment may be incorporated into another implementation as appropriate, unless expressly described otherwise, above. Although the description is made for particular arrangements and methods, the intent and concept thereof may be suitable and applicable to other arrangements and applications.

1. A cavity power meter comprising:
a plurality of sensing walls, each sensing wall of the plurality of sensing walls comprising:
an inner surface, and
a plurality of microbolometers connected to the inner surface, the plurality of microbolometers being part of a measurement circuit;
an aperture wall connected to the plurality of sensing walls,
the plurality of sensing walls and the aperture wall being arranged to enclose a volume defining a measurement cavity, the plurality of microbolometers of each sensing wall being disposed in the measurement cavity,
the aperture wall having an aperture defined therethrough, the aperture allowing electromagnetic radiation incident thereon to enter into the measurement cavity and to illuminate at least a portion of the plurality of microbolometers, thereby providing measurement of a power of the incident electromagnetic radiation.

2. The cavity power meter of claim 1, wherein, for each sensing wall, the plurality of microbolometers is arranged in a two-dimensional electrically interconnected array over the inner surface.

3. The cavity power meter of claim 1, wherein the aperture wall includes an interior layer of reflective material.

4. The cavity power meter of claim 3, wherein the interior layer of reflective material is formed from at least one of:
gold;
aluminum; and
silver.

5. The cavity power meter of claim 1, further comprising a plurality of aperture-wall microbolometers disposed on an inner surface of the aperture wall, the plurality of aperture-wall microbolometers being operatively connected to the plurality of microbolometers.

6. The cavity power meter of claim 1, wherein, for each sensing wall, the plurality of microbolometers covers a major portion of the inner surface.

7. The cavity power meter of claim 1, wherein:
the aperture is a through-hole; and
the aperture allows ambient air to flow in and out of the measurement cavity.

8. The cavity power meter of claim 1, further comprising a window disposed in the aperture; and
wherein the window sealingly closes the measurement cavity.

9. The cavity power meter of claim 8, wherein the plurality of sensing walls, the aperture wall, and the window are configured to maintain the measurement cavity in a vacuum condition.

10. The cavity power meter of claim 1, wherein at least one microbolometer of the plurality of microbolometers comprises an optically absorptive layer disposed on a cavity-side surface of the at least one microbolometer.

11. The cavity power meter of claim 10, wherein the optically absorptive layer includes at least one of:
gold black;
carbon nanotubes; and
graphene.

12. The cavity power meter of claim 1, wherein at least one sensing wall of the plurality of sensing walls further comprises a reflective layer disposed on at least a portion of the inner surface of the at least one sensing wall.

13. The cavity power meter of claim 1, further comprising:
a plurality of reference microbolometers thermally connected to the inner surface of at least one sensing wall of the plurality of sensing walls; and
wherein:
the plurality of microbolometers is a plurality of measurement microbolometers; and
the plurality of reference microbolometers is disposed in thermal contact with the at least one sensing wall.

14. The cavity power meter of claim 1, wherein:
the plurality of sensing walls includes a plurality of rectangularly-shaped sensing walls;
the aperture wall is rectangularly-shaped; and
the cavity power meter is in a rectangular cuboid form.

15. The cavity power meter of claim 14, wherein:
the aperture wall and the rectangularly-shaped sensing walls are square shaped; and
the cavity power meter is in a cube form.

16. The cavity power meter of claim 1, wherein:
the plurality of sensing walls includes a plurality of triangularly-shaped sensing walls; and
the aperture wall and the plurality of triangularly-shaped sensing walls have a pyramidal shape.

17. The cavity power meter of claim 16, wherein:
the plurality of triangularly-shaped sensing walls includes three triangularly-shaped sensing walls;
the aperture wall is triangularly-shaped; and
the cavity power meter is in a triangular pyramid form.

18. The cavity power meter of claim 16, wherein:
the plurality of triangularly-shaped sensing walls includes four triangularly-shaped sensing walls;
the aperture wall is square shaped; and
the cavity power meter is in a square pyramid form.

19. The cavity power meter of claim 16, wherein:
the plurality of triangularly-shaped sensing walls includes six triangularly-shaped sensing walls;
the aperture wall is hexagonally shaped; and
the cavity power meter is in a hexagonal pyramid form.

20. A method for measuring power of electromagnetic (EM) radiation using a cavity power meter, the cavity power meter including a plurality of electrically-interconnected microbolometers, the method comprising:
determining a change in at least one operational value across the plurality of electrically-interconnected microbolometers using an electrical substitution process, the change being due, at least in part, to the EM radiation entering a measurement cavity of the cavity power meter; and
measuring the power of the EM radiation, based on the change in the at least one operational value across the plurality of electrically-interconnected microbolometers,
using the electrical substitution process comprising:
determining an initial electrical resistance across the plurality of electrically-interconnected microbolometers, the initial electrical resistance being indicative of an initial temperature of the microbolometers, the initial electrical resistance being determined prior to the EM radiation entering the cavity power meter;
causing the EM radiation to enter the measurement cavity;
subsequent to the EM radiation entering the measurement cavity, determining an illumination electrical resistance across the plurality of electrically-interconnected microbolometers, the illumination electrical resistance being indicative of an effective illumination temperature of the microbolometers;
subsequent to determining the illumination electrical resistance, causing the EM radiation to discontinue entering the measurement cavity;
subsequent to causing the EM radiation to discontinue entering the measurement cavity, allowing the plurality of electrically-interconnected microbolometers to cool;
subsequent to allowing the plurality of electrically-interconnected microbolometers to cool, applying a substitution voltage across the plurality of electrically-interconnected microbolometers causing the plurality of electrically-interconnected microbolometers to return to the illumination electrical resistance; and
determining the power of the EM radiation based on the substitution voltage.
